(19) United States
(12) Patent Application Publication
(10) Pub. No.: US 2004/0228075 A1
(43) Pub. Date: Nov. 18, 2004

(54) Mobile terminal device with camera

(75) Inventors: Takashi Moriguchi, Yokohama-shi (JP); Shin Takahashi, Yokohama-shi (JP)

Correspondence Address: SCHULTE ROTH & ZABEL LLP, ATTN: JOEL E. LUTZKER, 919 THIRD AVENUE, NEW YORK, NY, 10022, US

(73) Assignee: Kyocera Corporation, Kyoto-shi (JP)

(21) Appl. No.: 10/785,291

(22) Filed: Feb. 23, 2004

(30) Foreign Application Priority Data
Feb. 24, 2003 (JP) 2003-045806

(51) Int. Cl. G06F 1/16; H05K 5/00; H05K 7/00

(52) U.S. Cl. 361/680

(57) ABSTRACT

A mobile phone device with a camera comprises a connecting section which connects a first casing and a second casing and a camera module which is disposed in the connecting section such that the optical axis should be along the axial line C. By doing this, it is possible to realize easy operability for taking pictures by the mobile terminal device having a camera module and obtain a sufficient length for the optical axis in the camera module.

Priority is claimed on Japanese Patent Application No. 2003-045806, filed Feb. 24, 2003, the content of which is incorporated herein by reference.

### BACKGROUND OF THE INVENTION

1. Field of the Invention

The present invention relates to a mobile terminal device with a camera which is provided with a camera module, such as a mobile phone device, a personal data assistant (hereinafter called a PDA), and a portable personal computer.

2. Description of Related Art

It is common that a mobile terminal device with a camera such as a mobile phone device which is provided with a camera module has a picture-capturing window on a back of a casing thereof such that an operator of the device can take a picture while observing a captured image which is displayed in a display section which is disposed on a front of the casing thereof.

In such a mobile terminal device in which two casings are connected via a hinge section so as to freely open and close, it is common that an optical system is disposed in a thickness direction of the hinge section in the hinge section so as to secure a certain length in an optical axis direction in the camera module. (See Japanese Unexamined Patent Application, First Publication No. 2000-253124.) Alternatively, it is common that an optical system is disposed along an axial line in the hinge section such that an incident light should be deflected by an optical member such as a prism. (See Japanese Unexamined Patent Application, First Publication No.2002-290523.) Also, it is possible to mention to a structure in which a casing having a display section is disposed so as to finely rotate around a second axial line which is orthogonal to an axial line of the hinge section such that the camera module is disposed in a desirable direction in the other casing. (See Japanese Unexamined Patent Application, First Publication No. 2001-320463.)

However, it has been difficult to obtain a sufficient length for the optical axis of the camera module by utilizing a thickness of the hinge section in a mobile terminal device to which more thinner portability has been required increasingly. Also, if an optical axis is disposed along the axial line of the hinge section, a deflecting element such as a prism or a mirror is necessary; thus, it is difficult to realize an accuracy for the optical axis. Also, there is a problem that such a structure may cause an increase in the cost of the device and the product weight. Furthermore, there is a problem that a structure around the hinge section is more complicated if the two casings are formed so as to freely rotate around two axial lines which are orthogonal to each other.

### SUMMARY OF THE INVENTION

The present invention was made in consideration of the above problems. An object of the present invention is to obtain a sufficient length for the optical axis for the camera module in the mobile terminal device with a camera module in a simple structure such that an easy operability should be realized for taking pictures.

For a solution for the above problems, a mobile terminal device with a camera comprises two casings which are overlapped on each other, connecting section for connecting said two casings so that said two casings rotate around an axial line in parallel with a direction in which said two casings are overlapped, and a camera module disposed inside of said connecting section with an optical axis of said camera module in parallel with said axial line.

In such a mobile terminal device with a camera, a camera module is disposed in a section of which thickness increases by connecting two casings such that the optical axes overlap in the thickness direction. By doing this, it is possible to obtain a sufficient length for the optical axis for the camera module without causing an increase in the thickness of the casings. Also, it is possible to save a space inside the casings because it is not necessary to have a space for disposing the camera module in the casings by containing the camera module in the connecting section.

A mobile terminal device with a camera according to the present invention further comprises a display section which displays an image which is taken by said camera module. In this aspect of the present invention, it is characterized in that said display section is disposed so as to be orthogonal substantially to said axial line of either one of said two casings.

According to such as mobile terminal device with a camera, it is possible to observe an image to be taken thereof which is displayed in the display section such that a lens of the camera module is disposed toward an object to be shoot. In such a case, it is not necessary to deflect an incident light into the lens because the optical axis of the camera module is disposed substantially orthogonal to the display section.

A mobile terminal device with a camera according to the present invention further comprises a sensor which measures a relative angle made by one of said two casings on which said camera module is disposed and the other of said two casings on which said display section is disposed. In this aspect of the present invention, it is characterized in that an image which is taken by said camera module is displayed on said display section in a rotated manner according to the measurement result by said sensor.

In such a mobile terminal device with a camera, an image to be taken is processed such that the image to be taken is displayed in a rotated manner by the display section according to the relative angle made by the camera module and the casing. Therefore, it is possible that the camera module can be disposed so as to coincide with a direction of the image to be taken.

In a mobile terminal device with a camera according to the present invention, it is characterized in that said cameral module is fixed to said casing in which said display section is disposed.

In a mobile terminal device of the present invention, it is characterized in that an image which is taken by said camera module is rotated by 90 degrees with no change to the aspect ratio of said image and then is displayed on said display section when the measurement result is that said relative angle is 90 degrees.

Also, in a mobile terminal device with a camera according to the present invention, it is characterized in that said mobile terminal device with a camera is a portable telephone.

Also, a mobile terminal device with a camera according to the present invention comprises two casings which can be overlapped on each other, a connecting section for connecting said two casings so that said two casings rotate around an axial line in parallel with a direction in which said two casings are overlapped such that said connecting section has a fixed base member which is fixed on one of said two casings and a movable base member which is fixed on the other of said two casings and is fit in the peripheral surface of said fixed base member rotatably around said axial line, a hollow space provided in said fixed base member, and a camera module disposed inside of said hollow space, with an optical axis in parallel with said axial line.

In a mobile terminal device with a camera of the present invention further comprises a fixed cylinder as part of said camera module, which acts as a casing for said camera module, a cam cylinder as part of said camera module, which is fit in the peripheral surface of said fixed cylinder movably along said axial line, a linear groove provided on the peripheral wall of said fixed cylinder in parallel with said axial line, a cam groove provided on the peripheral wall of said cam cylinder in parallel with said axial line, and a pin provided with a lens on the tip thereof, which penetrates said linear groove to connect with said cam groove movably along said axial line.

In a mobile terminal device with a camera according to the present invention, it is characterized in that said mobile terminal device with a camera is a portable telephone.

In such a mobile terminal device with a camera, the camera module and the display section do not rotate relatively to each other; thus, the image to be taken which is displayed in the display section can be disposed to so as to coincide a direction of the camera module without any particular processing operation to the image to be taken.

As explained above, according to the present invention, it is possible to obtain a sufficient length for the optical axis for the camera module without increasing the thickness of the casings. Therefore, it is possible to realize a more flexible design for the optical system in the camera module; thus, it is possible to mount a camera module which is provided with an optical zooming function having not only a single-focal distance camera module but also a longer optical axis. By doing this, it is possible to add more commercial value for the mobile terminal device with a camera. Also, it is possible to save a space in each casing. By doing this, it is possible to realize a more flexible design for the casings and circuit boards; thus, it is possible to add more commercial value of the mobile terminal device with a camera.

According to the present invention, it is possible for an operator of the mobile terminal device with a camera to take a picture of a image while disposing a lens of the camera module to an object to be taken and observing an image to be taken which is displayed in the display section such that pictures can be taken naturally uninterrupted manner. Also, the optical axis of the camera module is disposed substantially orthogonal to the display section; therefore, it is not necessary to deflect the incident light which is incident to the lens surface. Thus, it is possible to realize a more accurate optical axis and reduce the cost and the weight of the mobile terminal device with a camera.

Also, according to the present invention, the camera module can be always disposed so as to coincide with a direction of the image to be taken even if the the casing to which the display section is disposed and the camera module are rotated relatively to each other. Thus, it is possible for an operator of the mobile terminal device with a camera to take a picture while observing the image to be taken which is displayed in the display section such That pictures can be taken naturally uninterrupted manner.

According to the present invention, the camera module and the display section do not rotate relatively to each other. In addition, the image to be taken which is displayed in the display section can be disposed so as to coincide the direction of the camera module. Therefore, it is possible for an operator of the mobile terminal device with a camera to take a picture while observing the image to be taken which is displayed in the display section such that pictures can be taken naturally uninterrupted manner. Also, a time for processing the images is not necessary; thus, it is possible to reduce a time for processing pictured images. Also, it is possible to save electricity which is consumed in the device.

### BRIEF DESCRIPTION OF THE DRAWINGS

FIG. 1 is a perspective view for a mobile phone device as an example for a mobile terminal device with a camera according to the present invention.

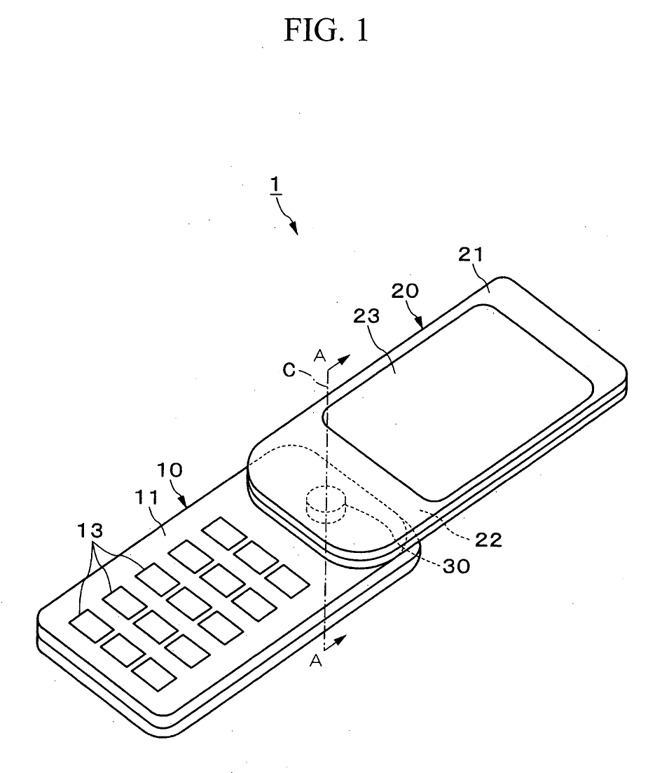

FIG. 2 is a perspective assembly view for the mobile phone device shown in FIG. 1.

FIG. 3 is a cross sectional for the mobile terminal device with a camera according to a first embodiment viewed in line A-A shown in FIG. 1.

FIGS. 4A to 4C are front views for a mobile phone device for explaining processing operations for images to be taken which are displayed in a display section. FIG. 4A shows the mobile phone device under opened condition. FIG. 4B shows the mobile phone device under rotated condition by 90 degrees from the opened condition. FIG. 4C shows the mobile phone device under closed condition.

FIG. 5 is a cross sectional view for the mobile terminal device with a camera according to a second embodiment viewed in line A-A shown in FIG. 1.

### DETAILED DESCRIPTION OF THE JNVENTION

A first embodiment of the present invention is explained below with reference to drawings. Here, a mobile phone device with a camera is explained for an example for the first embodiment of the mobile terminal device with a camera according the present invention.

As shown in FIG. I, the mobile phone device (mobile terminal device) 1 is provided with a first casing 10 and a second casing 20 which are formed in flat rectangular shape. A side end section of a front surface 11 of the first casing 10 and a side end section of a rear surface 22 of the second casing 20 can be overlapped on each other. A connecting section 30 is disposed in an overlapped section of the casings 10 and 20 such that the both casings 10 and 20 should be rotated relatively to each other around an axial line C which is orthogonal substantially to the front surface 11 and the rear surface 22. Thus, such a mobile phone device has multi-stage structure.

Operation keys 13 such as ten-keys are disposed on the front surface of the first casing 10. A display section 23 such as a liquid crystal display device is disposed on a front surface 21 of the second casing 20. In addition, as shown in the drawing, it should be understood that the mobile phone device 1 is opened if the front surface 11 of the first casing 10 is exposed thereoutside. When both of the casings 10 and 20 rotate relatively to each other form such an opened position, the casings 10 and 20 overlap each other such that outlines of the casings coincide with each other substantially. In other words, it should be understood that the mobile phone device 1 is closed if the front surface 11 of the first casing 10 is covered by the second casing 20.

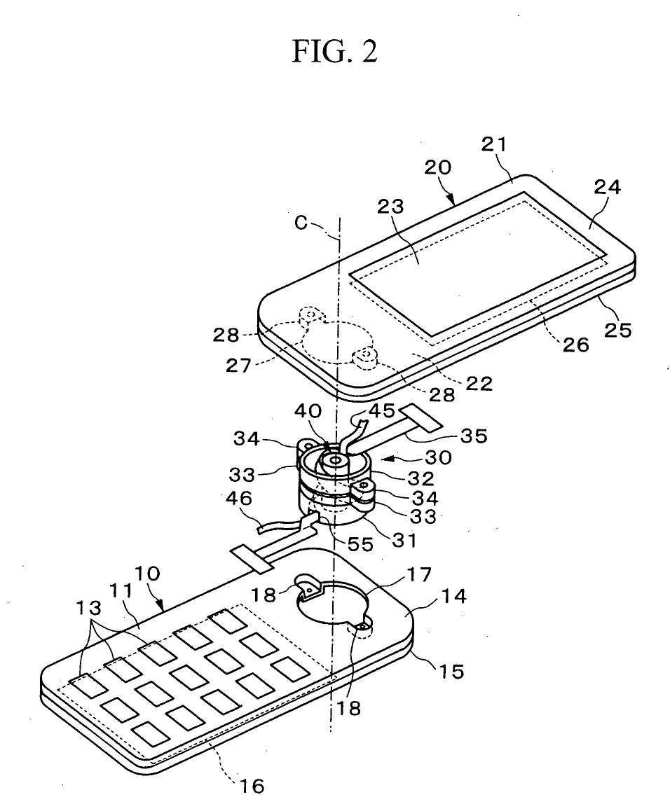

As shown in FIG. 2, the first casing 10 comprises a front casing 14 and a rear casing 15 such that units such as operation keys 13 and a circuit board 16 are contained in the first casing 10. Also, as shown in FIG. 2, the second casing 20 comprises a front casing 24 and a rear casing 25 such that units such as a display section 23 and a circuit board 26 are contained in the second casing 20.

A connecting unit 30 is provided with a fixed base member 31 which is formed in an substantial cylinder having an axial line C in the center thereof and a movable base member 32 which is fitted in an outer periphery of the fixed base member 31 nearer to the second casing 20 rotatably around the axial line C. Also, a pair of attaching members 33, 33 are disposed on an outer periphery of the fixed base member 31 so as to be outside in an radial direction. Also, a pair of attaching members 34, 34 are disposed on the movable base member 32.

On the other hand, an insertion hole 17 is formed on an end section of the front casing 14 on the first casing 10 so as to attach the fixed base member 31 thereon. Also, a pair of fixing members 18, 18 are formed on two positions closely outside of the insertion hole 17 so as to correspond to the attaching members 33, 33. Also, an insertion hole 27 is formed on an end section of the rear casing 25 on the second casing 20 so as to attach the movable base member 32 thereon. Also, a pair of fixing members 28, 28 are formed on two positions closely outside of the insertion hole 27 so as to correspond to the attaching members 34, 34.

Consequently, the fixed base member 31 is attached to the insertion bole 17 which is formed on the first casing 10. The attaching members 33, 33 are fixed to the fixing members 18, 18 so as to correspond thereto. Also, the movable base member 32 is attached to the insertion hole 27 which is formed on the second casing 20. The attaching sections 34, 34 are fixed to the fixing members 28, 28 so as to correspond thereto. By doing this, the first casing 10 and the second casing 20 are connected so as to rotate relatively to each other around the axial line C via the connecting unit 30.

Here, the connecting unit 30 is formed rigid so as to endure a load such as a force, which is generated by the relative rotational movement by the casings 10 and 20. Such a rigid structure is realized, for example, by forming the connecting unit 30 by a metal member. Here, a clicking structure which is not shown in the drawing is built in the connecting unit 30 such that an operator can feel a click for the relative movement by the both casings 10 and 20 on the mobile phone device 1 in various condition such as an opened condition and a closed condition.

In addition, a camera module 40 is contained in a hollow space in the connecting unit 30 such that a central axial line of the camera module 40 coincides with the axial line C. Here, a flexible base board 35 which passes in the connecting unit 30 spirally is wound around the camera module 40 not so tightly such that the flexible base board 35 communicates between the casings 10 and 20 so as to connect the circuit boards 16 and 26 electrically.

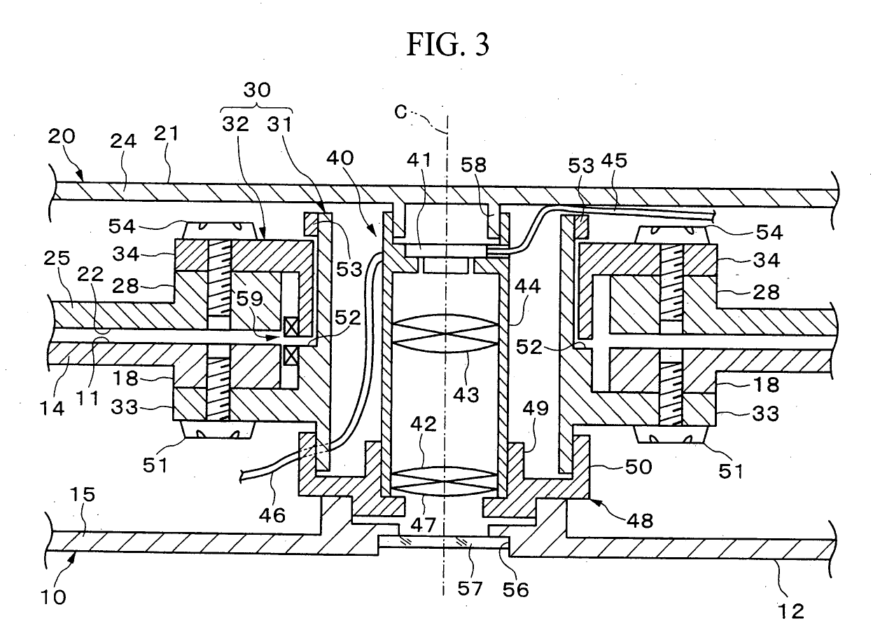

As shown in FIG. 3, the camera module 40 comprises an image taking element section 41 such as a CMOS (complementary metal-oxide semiconductor) and a CCD (charge-coupled device) and two lenses 42 and 43 which forms an image of the object to be taken on a focal plane of the image taking element section 41. Thus, the camera module 40 is formed so as to be a single-focal-distance camera in which these members are contained and fixed in a cylindrical casing 44. An image of an object to be taken which is focused on a focal plane of the image taking element section 41 is converted to an electric signal, and such a image to be taken is displayed in the display section 23. Here, reference numeral 45 indicates a cable which connects the image taking element section 41 and the base board 26 which is formed in the second casing 20. Reference numeral 46 indicates a cable which is connected to the base board 16 in the first casing 10 for controlling the camera for activating a shutter.

Here, an optical axis of the camera module 40 is disposed on a central axial line of the casing 44. In the camera module 40, a lens surface 47 is disposed near the first casing 10 toward the object to be taken and an image taking element section 41 is disposed near the second casing 20.

An substantial circular camera fixing member 48 is disposed on a tip of the lens surface 47 in the camera module 40. An outer periphery of the casing 44 is fixed so as to fit in a circular rib 49 which stand near the camera module 40. Also, an end section of the fixed base member 31 which is nearer to the first casing to in the connecting unit 30 is fixed to an outer periphery circular rib 50 which stand on an outer periphery of the camera fixing member 48. In addition, the attaching sections 33, 33 of the fixed base member 31 are fixed to the fixing members 18, 18 on the first casing 10 via screws 51, 51 respectively. Therefore, the camera module 40 is fixed to the first casing 10 via the camera fixing member 48 and the fixed base member 31.

A position of the movable base member 32 which is fitted nearer to the secon casing 20 which is formed on the fixed base member 31 in a direction of the axial line C is set by a step section 52 which is formed on an outer periphery of the fixed base member 31 and a stop ring 53 which is fixed on an end section nearer to the second casing 20 which is formed on the fixed base member 31. Also, attaching members 34, 34 on the movable base member 32 are fixed to the fixing members 28, 28 on the second casing 20 via screws 54, 54. Here, the camera fixing member 48 also serves for preventing the cable 46 and the flexible base board 35 from protruding the connecting unit 30. A notched section 55 is disposed on an end section of the fixed base member 31 nearer to the first casing 10 so as to pull the cable 46 and the flexible base board 35 from the connecting unit 30. (See FIG. 2.)

A picture-capturing window 56 having an aperture on a rear surface 12 of the first casing 10 is formed so as to correspond to the lens surface 47 of the camera module 40 on the rear casing 15 on the first casing 10. A lens trim 57 which is formed by, for example, a transparent acrylic board is attached to the picture-capturing window 56 by a two-sided bonding tape so as to protect the lens 42 which is disposed nearer to the picture-capturing window 56 in the camera module 40 and prevent undesirable members from coming thereinside. A circular rib 58 is disposed so as to stand in a corresponding position which faces the end section of the camera module 40 nearer to the second casing 20 on a back side of the front casing 24 of the second casing 20. The circular rib 58 fits in the casing 44 of the camera module 40 from an inner periphery of the casing 44; thus, the end section of the camera module 40 nearer to the second casing 20 is supported by the front casing 24 so as to freely rotate around the axial line C.

Here, the camera module 40 is fixed to the first casing 10; therefore, the display section 23 which displays the image to be taken rotates together with the second casing 20 relatively against the camera module 40 if both of the casings 10 and 20 rotate relatively. In such a case, the image to be taken which is displayed On the display section 23 is processed according to the measurement signal which is generated by a relative angle sensor 59 which is disposed in the connecting unit 30 so as to measure the relative angle made by the camera module 40 and the casing 20. Thus, the image to be taken is rotated in the display section 23; therefore, a direction of the camera module 40 and a direction of the image to be taken which is displayed in the display section 23 are adjusted accordingly.

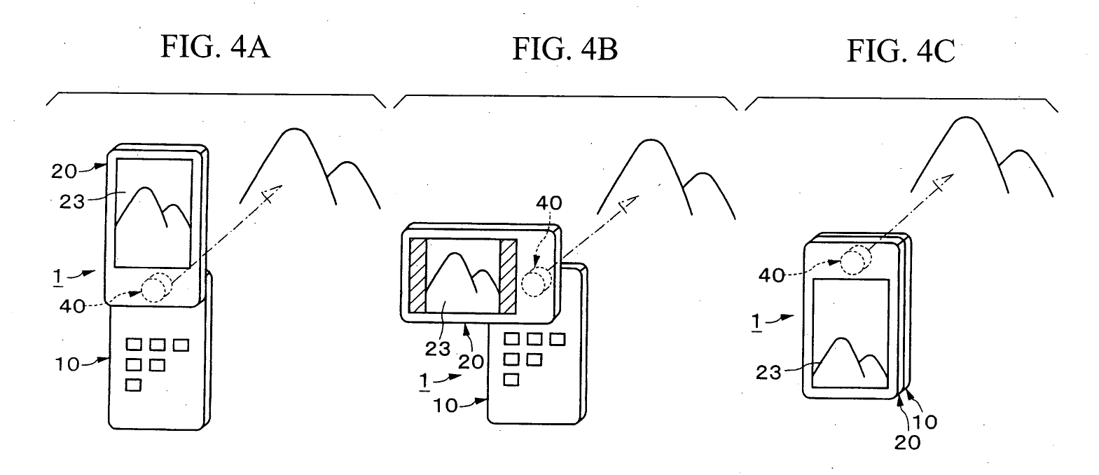

More specifically, as shown in FIG. 4A in which the mobile phone device 1 is under an opened condition, an upward direction for the camera module 40 and an upward direction for the image to be taken which is displayed in the display section 23 coincide with each other. In such a case, as shown in FIG. 4B, if the second casing 20 rotates by 90 degrees in a counter clockwise direction viewed from the front end 21, the image to be taken which is displayed in the display section 23 is processed such that the image to be taken should be displayed under rotated condition by 90 degrees in a clockwise direction. By doing this, the direction of the camera module 40 and the direction of the image to be taken which is displayed in the display section 23 coincide with each other. In addition, as shown in FIG. 4C, if the second casing 20 rotates by additional 90 degrees in a counter-clockwise direction, that is, under closed condition of the mobile phone device 1, the image to be taken which is displayed in the display section 23 is processed such that the image to be taken should be displayed under rotated condition by additional 90 degrees in a clockwise direction. By doing this, the direction of the camera module 40 and the direction of the image to be taken which is displayed in the display section 23 coincide with each other.

In the mobile phone device 1 according to the first embodiment of the present invention, the camera module 40 which is disposed such that the optical axis coincides with the axial line C is contained in the connecting unit 30 which connects the first casing 10 and the second casing 20 which are overlapped on each other so as to freely rotate around the axial line C which is along the direction in which the first casing 10 and the second casing 20 are overlapped. The lens surface 47 in the camera module 40 is directed to the object to be taken via the picture-capturing window 56 which is disposed on a rear surface 12 of the first casing 10. Thus, it is possible for an operator of the mobile terminal device with a camera to take a picture of a image while observing an image to be taken which is displayed in the display section which is disposed on the front surface 21 on the second casing 20 such that pictures can be taken in a naturally uninterrupted manner.

Here, the optical axis in the camera module 40 is disposed so as to be along the thickness direction of the overlapped section of the casings 10 and 20; thus, it is possible to obtain a sufficient length for the optical system in the camera module which as substantially twice as long as the thickness of the casings 10 and 20 without increasing the thickness of the casings 10 and 20. Also, it is possible to realize a more flexible design for the optical system in the camera module 40. In addition, it is not necessary to deflect the optical axis of the incident light which is incident to the camera module 40 by an optical member such as a mirror or a prism; therefore, it is possible to realize a more accurate optical axis and reduce the cost of the device.

Also, the camera module 40 is contained in a hollow space in the connecting unit 30. By doing this, it is not necessary to secure a space for dispose the camera module 40 in the casings 10 and 20. Therefore, it is possible to realize a more flexible design for the casings 10, and 20, and the circuit boards 16 and 26. Also, the camera module 40 is contained in the connecting unit 30 which has relatively a rigid structure; it is possible to restrict an undesirable influence such as a physical impact or a load to the camera module 40. Here, the lens surface 47 in the camera module 40 is fixed to the first casing 10; therefore, it is easy to seal a near portion of the lens surface 47. Thus, it is possible to prevent undesirable members from coming into the camera module 40 easily.

Furthermore, the optical axis in the camera module 40 coincides with the central axial line of the casing 44; therefore, it is possible to align the optical axis of the camera module 40 with the axial line of the connecting unit 30 easily. Also, it is possible to improve an operability for assembling the mobile phone device 1 by assembling the camera module 40 and the connecting unit 30 unitarily in advance.

Additionally, it is possible to take a picture while observing an image to be taken which is displayed in the display section 23 which is disposed on the front surface 21 on the second casing 20 with regardless to conditions as to whether the mobile phone device 1 is opened or closed, and as to relative position between the casings 10 and 20. Also, it is possible to display the image which is taken by the camera module 40 in the display section 23 under condition that the direction of the image to be taken is processed to be disposed in accordance with the direction of the camera module 40 by a relative angle sensor 59 which measures a relative angle which is made by the camera module 40 and the second casing 20. Therefore, it is possible to change the relative position between the casings 10 and 20 under various conditions such as taking a picture by the mobile phone device 1 in one of hands or taking a picture by both hands so as to hold the mobile phone device 1 for preventing the camera from shaking. Thus, it is possible for an operator to take a picture while observing the image which is displayed in the display section 23 such that pictures can be taken in naturally uninterrupted manner.

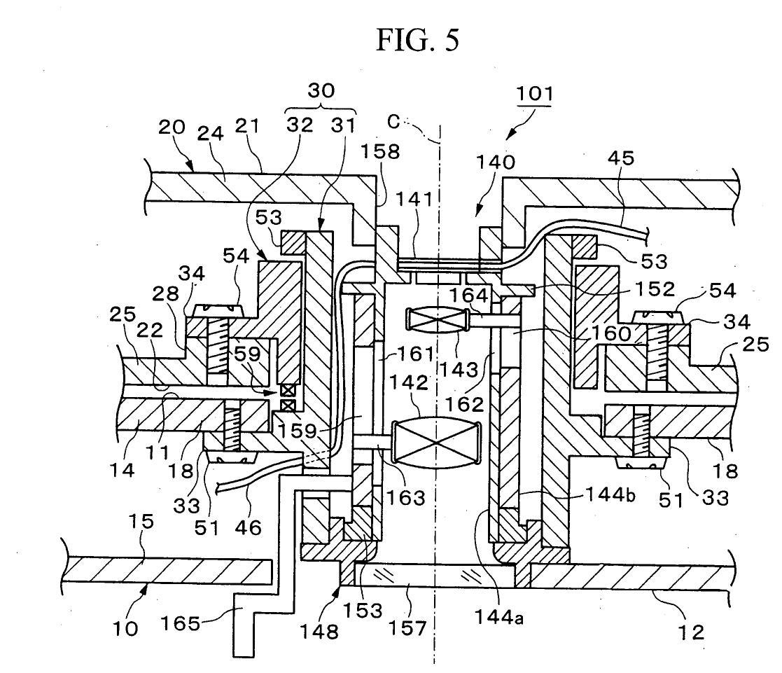

Next, a second embodiment of the present invention is explained below with reference to FIG. 5.

A mobile phone device with a camera 101 in the present embodiment is provided with the same members in the mobile phone device 1. The mobile phone device with a camera 101 is different from the mobile phone device 1 only in that the mobile phone device with a camera 101 is provided with a camera module 140 having an optical zooming function in place of the camera module 40. Hereinafter, the same reference numerals are applied to corresponding members as shown in FIG. 3 so as to omit the repeated explanation thereof.

As shown in FIG. 5, the camera module 140 in the mobile phone device with a camera 101 is provided with a zooming structure which is known commonly which is provided with a fixed cylinder 144a and a cam cylinder 144b. The fixed cylinder 144a serves as a casing which contains an image taking element section 141, lenses 142 and 143 such that the central axial line of the fixed cylinder 144a coincides with the optical axis and the axial line C of the camera module 140. The cam cylinder 144b which moves the lenses 142 and 143 relatively in the optical axis direction of the fixed cylinder 144a is fitted in an outer periphery of the fixed cylinder 144a so as to freely rotate around the axial line C. The axial line C of the cam cylinder 144b is positioned by a flange section 152 which is disposed on the fixed cylinder 144a so as to be nearer to the second casing 20 and a fixing Ting 153 which is fixed to an end section of the first casing 10. The end section which is disposed on the fixed cylinder 144a so as to be nearer to the first casing 140 is fixed to a camera fixing member 148 via a fixing ring 153. Also, the camera module 140 is fixed to the first casing 10 via the fixing ring 153, the camera fixing member 148, and the fixed base member 31 on the connecting unit 30. Here, a lens trim 157 is attached to the camera fixing member 148 directly so as to form a picture-capturing window on the camera module 140.

A circular rib 158 of which center coincides with the axial line C is disposed so as to stand on a front casing 24 on the second casing 20 so as to face a portion of the camera module 140 which faces the end section of the second casing 20. Thus, the circular rib 158 fits in the outer periphery of the fixed cylinder 144a of the camera module 140 so as to freely rotate therearound.

Cam grooves 159, 160 having desirable spiral shape are formed around an outer wall of the cam cylinder 144b Also, linear grooves 161, 162 which extend in parallel with an optical axis are formed around an outer wall of the fixed cylinder 144a. Pins 163, 164 which extend from holders radially for supporting the lenses 142, 143 pass through the linear grooves 161, 162 correspondingly so as to be connected to the cam grooves 159, 169 movably. Consequently, if the cam cylinder 144b rotates around the fixed cylinder 144a, the pins 163, 164 move along the linear grooves 161, 162 on the fixed cylinder 144a while the pins 163, 164 are guided to the cam grooves 159, 160 on the cam cylinder 144b. Thus, the lenses 142, 143 move in the optical axis direction. By doing this, the focal distance is adjusted to be telescopic or wide-angle.

Here, an operation crank lever 165 is attached to the cam cylinder 144b on the camera module 140 such that a tip of the operation crank lever 165 protrude toward a rear surface 12 of the first casing 10. Additionally, the cam cylinder 144b starts rotating if the operation lever 165 is activated; thus, the lenses 142, 143 move in the optical axis direction Thus, it is possible to change the focal distance. That is, it should be understood that the zooming structure in the camera module 140 may be realized by a manual operation.

In the mobile phone device with a camera 101 according to the second embodiment, the camera module 140 is contained in the connecting unit 30 which connects the first casing 10 and the second casing 20 such that the first casing 10 and the second casing 20 should rotate freely relatively. By doing this, it is possible to dispose the lens trim 157 which is exposed to the rear surface 12 of the first casing 10 toward the object to be taken. Thus, it is possible to take a picture of a image while observing an image to be taken which is displayed in the display section 23 which is disposed on the front surface 21 of the second casing 20 such that pictures can be taken in naturally uninterrupted manner. The camera module 140 is provided with an optical zooming structure having quite a long optical system. However, it is possible to dispose the optical axis along the direction in which the casings 10 and 20 which are overlapped if thickness of the overlapped section is utilized efficiently. Thus, it is possible to realize a more accurate optical axis and reduce the cost of the device without deflecting the optical axis of the light which is incident to the camera module 140.

Also, it is possible to save a space in the connecting unit 30 by utilizing a hollow space in the connecting unit 30. Thus, it is possible to realize a more flexible design for the casings 10 and 20 and the circuit boards 16 and 26. Also, it is possible to protect the camera module 140 by the connecting unit 30. Furthermore, it is possible to align the central axial line of the camera module 140 and the axial line of the connecting unit 30 easily because the central axis line of the camera module 140 coincides with the optical axis. If the camera module 140 and the connecting unit 30 are formed unitarily in advance, it is possible to assemble these members in the mobile phone device 1 efficiently.

Also, it is possible to change the relative position between the casings 10 and 20 in accordance with various conditions; thus, it is possible to take a picture while observing an image to be taken which is displayed in the display section 23 such that pictures can be taken in naturally uninterrupted manner.

Here, it is apparent that the specific structural and functional details disclosed herein are merely representative and do not limit the scope of the present invention. For example, it may be acceptable if the camera modules 40, 140 may be fixed to the second casing 20 such that the camera modules 40 and 140 should be connected to the first casing 10 so as to freely rotate around the axial line C. By doing this, the camera modules 40 and 140 rotate together with the display section 23. In such a case, it is not necessary to process the images so as to align the direction of the image to be taken which is displayed in the display section 23 to the direction of the camera modules 40 and 140. Therefore, it is possible to reduce a time for processing the image to be taken and save the electricity. In such a case, if the circuit board 26 in the second casing 20 is extended near the axial line C so as to be connected to the end sections of the camera modules 40 and 140 directly, it is possible to realize a simple structure without a cable 45. Also, it is possible to increase the area for the base board; thus, it is possible to realize a more flexible design for the device.

Also, it may be acceptable if the optical axes of the camera modules 40 and 140 are directed so as to be eccentric in the connecting unit 30 as long as the optical axes of the camera modules 40 and 140 are parallel to the axial line C substantially.

Furthermore, in the second embodiment, it may be acceptable if the zooming structure in the camera module 140 is realized in a manual manner or an electric manner using a motor and gears.

Also, the present invention is not limited to a mobile phone device. That is, it is possible to apply the present invention to various mobile terminal devices which are provided with a camera module such as a mobile personal computer.

What is claimed is:

1. A mobile terminal device with a camera comprising:
two casings which are overlapped on each other;
connecting section for connecting said two casings so that said two casings rotate around an axial line in parallel with a direction in which said two casings are overlapped; and
a camera module disposed inside of said connecting section with an optical axis of said camera module in parallel with said axial line.

2. A mobile terminal device with a camera according to claim 1 further comprising a display section which displays an image which is taken by said camera module, wherein said display section is disposed so as to be orthogonal substantially to said axial line of either one of said two casings.

3. A mobile terminal device with a camera according to claim 2 further comprising a sensor which measures a relative angle made by one of said two casings on which said camera module is disposed and the other of said two casings on which said display section is disposed, wherein an image which is taken by said camera module is displayed on said display section in a rotated manner according to the measurement result by said sensor.

4. A mobile terminal device with a camera according to claim 2 wherein said cameral module is fixed to said casing in which said display section is disposed.

5. A mobile terminal device with a camera according to claim 3, wherein an image which is taken by said camera module is rotated by 90 degrees with no change to the aspect ratio of said image and then is displayed on said display section when the measurement result is that said relative angle is 90 degrees.

6. A mobile terminal device with a camera according to claim 1, wherein said mobile terminal device with a camera is a portable telephone.

7. A mobile terminal device with a camera, comprising:
two casings which can be overlapped on each other;
a connecting section for connecting said two casings so that said two casings rotate around an axial line in parallel with a direction in which said two casings are overlapped, wherein said connecting section has a fixed base member which is fixed on one of said two casings and a movable base member which is fixed on the other of said two casings and is fit in the peripheral surface of said fixed base member rotatably around said axial line;
a hollow space provided in said fixed base member, and
a camera module disposed inside of said hollow space, with an optical axis in parallel with said axial line.

8. A mobile terminal device with a camera according to claim 7, further comprising:
a fixed cylinder as part of said camera module, which acts as a casing for said camera module;
a cam cylinder as part of said camera module, which is fit in the peripheral surface of said fixed cylinder movably along said axial line;
a linear groove provided on the peripheral wall of said fixed cylinder in parallel with said axial line;
a cam groove provided on the peripheral wall of said cam cylinder in parallel with said axial line; and
a pin provided with a lens on the tip thereof, which penetrates said linear groove to connect with said cam groove movably along said axial line.

9. A mobile terminal device with a camera according to claim 7, wherein said mobile terminal device with a camera is a portable telephone.
